(19) United States
(12) Patent Application Publication
(10) Pub. No.: US 2026/0123044 A1
(43) Pub. Date: Apr. 30, 2026

(54) SEMICONDUCTOR STRUCTURE WITH STACKED TRANSISTORS

(71) Applicant: TAIWAN SEMICONDUCTOR MANUFACTURING COMPANY, LTD., Hsinchu (TW)

(72) Inventors: Meng-Yu LIN, New Taipei City (TW); Ping HUANG, Hsinchu City (TW); Chun-Fu CHENG, Hsinchu County (TW)

(73) Assignee: TAIWAN SEMICONDUCTOR MANUFACTURING COMPANY, LTD., Hsinchu (TW)

(21) Appl. No.: 18/930,530

(22) Filed: Oct. 29, 2024

(51) Int. Cl. H01L 27/092; H01L 21/822; H01L 21/8238; H01L 29/06; H01L 29/423; H01L 29/66; H01L 29/775; H01L 29/786

(52) U.S. Cl. CPC H10D 84/856; H10D 30/014; H10D 30/43; H10D 30/6735; H10D 30/6757; H10D 62/121; H10D 64/017; H10D 84/0188; H10D 84/038; H10D 88/01

(57) ABSTRACT

A method includes following steps. Semiconductor nanostructures are formed arranged one above another over a substrate. A lower gate electrode is formed surrounding a first subset of the plurality of semiconductor nanostructures. An upper gate electrode is formed surrounding a second subset of the plurality of semiconductor nanostructures. An upper gate isolation structure is formed extending from a top surface of the upper gate electrode into the upper gate electrode. After completing the formation of the upper gate isolation structure, a lower gate isolation structure is formed extending from a bottom end of the upper gate isolation structure into the lower gate electrode.

### BACKGROUND

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

As the semiconductor industry further progresses into sub-10 nanometer (nm) technology process nodes in pursuit of higher device density, higher performance, and lower costs, challenges from both fabrication and design issues have led to stacked device structure configurations, such as complementary field effect transistors (CFET) where an n-type multi-gate transistor and a p-type multi-gate transistor are stacked vertically, one over the other. While existing CFET structures are generally adequate, they are not satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a complementary field-effect transistor (CFET) schematic in a three-dimensional view, in accordance with some embodiments.

FIGS. 2-12 are three-dimensional views and cross-sectional views of a CFET device at various stages of manufacturing, in accordance with some embodiments of the present disclosure.

FIGS. 13-14 are cross-sectional views of a CFET device at various stages of manufacturing, in accordance with some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced with the down-scaling of the integrated circuits.

According to various embodiments, CFETs are formed. A CFET includes a lower nanostructure-FET and an upper nanostructure-FET. An isolation structure (also referred to as a nanostructure isolation material) is formed between the nanostructures of the lower nanostructure-FET and the nanostructures of the upper nanostructure-FET. A cut metal gate (CMG) isolation structure, created through a CMG etching process, extends vertically into the gate regions of both the upper and lower nanostructure-FETs. This CMG isolation structure separates the continuous gates of both the upper and lower nanostructure-FETs into multiple discontinuous gates. However, the height of the CMG isolation structure increases due to the cumulative height of the stacked FETs. This increased height results in an aggravated tapered profile, causing the lower portion of the CMG isolation structure to have an excessively narrow width. The reduced width at the bottom portion of the CMG isolation structure leads to higher gate-to-gate capacitance between the discontinuous gates of the lower nanostructure-FETs.

To address this issue, the present disclosure, in various embodiments, provides a dual-side CMG formation process. This process involves forming a front-side CMG (FCMG) isolation structure by etching the front-side of the gate of the stacked FETs, and forming a backside CMG (BCMG) isolation structure by etching the backside of the gate of the stacked FETs. By employing this dual-side CMG formation process, the minimum width of the combined FCMG and BCMG isolation structures can be increased, thereby mitigating the unwanted increase in gate-to-gate capacitance.

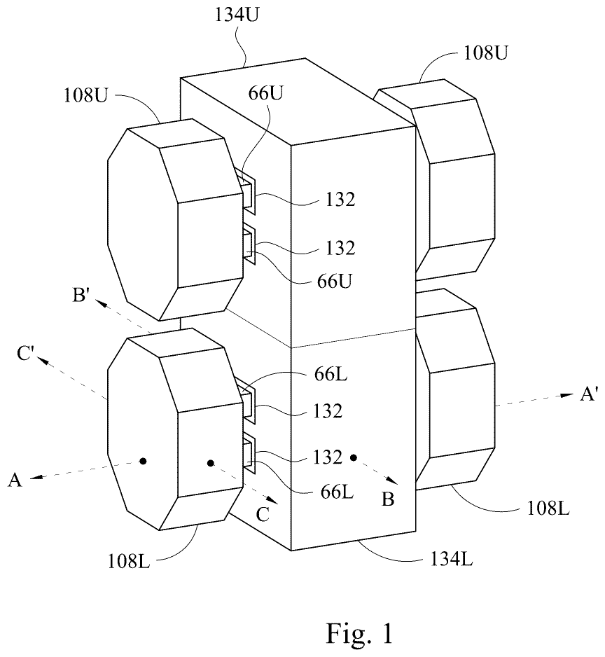

FIG. 1 illustrates an example of a CFET schematic, in accordance with some embodiments. FIG. 1 is a three-dimensional view, where some features of the CFETs are omitted for illustration clarity.

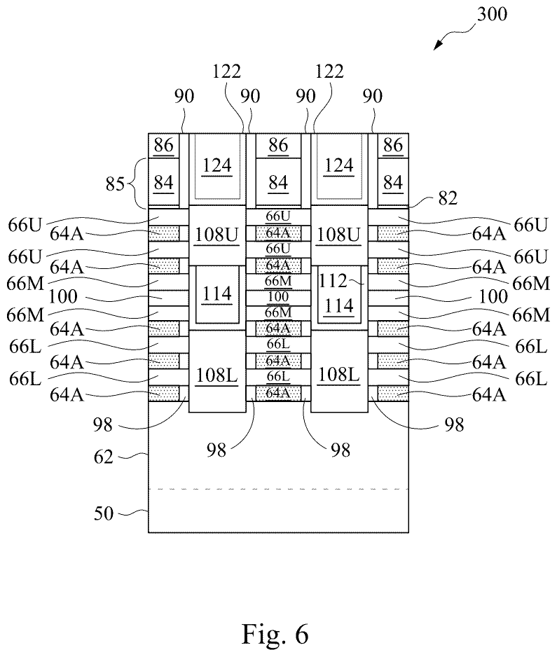

The CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET may include a lower nanostructure-FET of a first device type (e.g., n-type/p-type) and an upper nanostructure-FET of a second device type (e.g., p-type/n-type) that is opposite the first device type. Specifically, the CFET may include a lower PMOS transistor and an upper NMOS transistor, or the CFET may include a lower NMOS transistor and an upper PMOS transistor. Each of the nanostructure-FETs include semiconductor nanostructures 66 (including lower semiconductor nanostructures 66L and upper semiconductor nanostructures 66U), where the semiconductor nanostructures 66 act as channel regions (also referred to as channel layers, semiconductor channels regions, or semiconductor channel layers) for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A nanostructure isolation material (not explicitly illustrated in FIG. 1, see 100 in FIG. 6) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. Source/drain regions 108 (including lower epitaxial source/drain regions 108L and upper epitaxial source/drain regions 108U) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U by an isolation layer. Alternatively, a lower gate electrode 134L may be coupled to an upper gate electrode 134U. Further, the upper epitaxial source/drain regions 108U may be separated from lower epitaxial source/drain regions 108L by one or more dielectric layers. The isolation features between channel regions, gates, and source/drain regions allow for vertically stacked transistors, thereby improving device density. Because of the vertically stacked nature of CFETs, the schematic may also be referred to as stacking transistors or folding transistors.

FIG. 1 further illustrates reference cross-sections that are used in later figures. Cross-section A-A′ is parallel to a longitudinal axis of the semiconductor nanostructures 66 of a CFET and in a direction of, for example, a current flow between the source/drain regions 108 of the CFET. Cross-section B-B′ is perpendicular to cross-section A-A′ and along a longitudinal axis of a gate electrode 134 of a CFET. Cross-section C-C′ is parallel to cross-section B-B′ and extends through the source/drain regions 108 of the CFETs. Subsequent figures refer to these reference cross-sections for clarity.

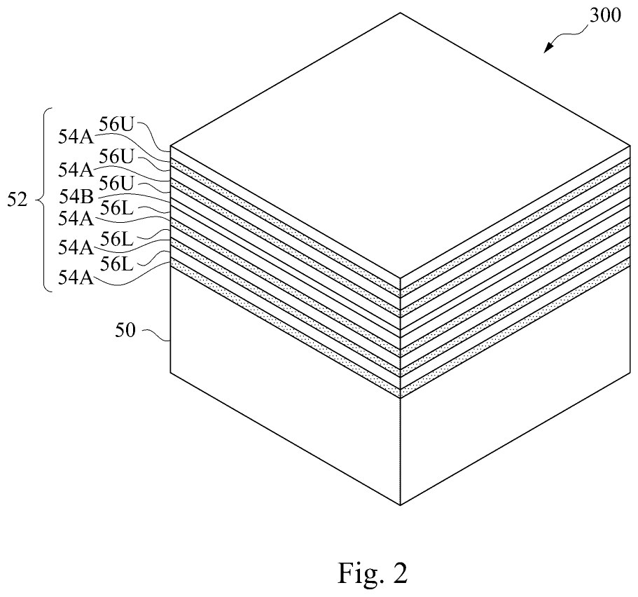

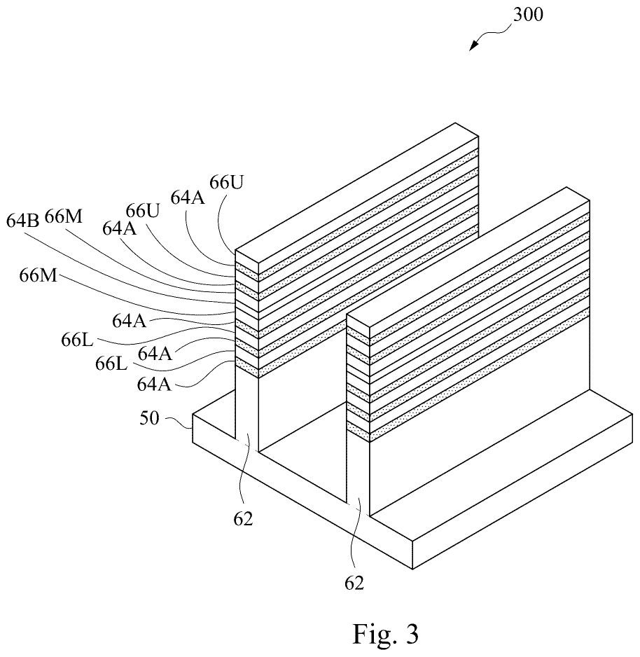

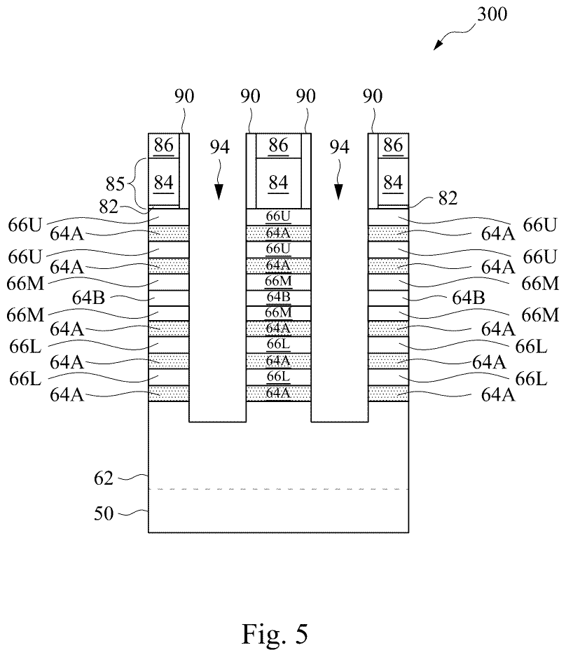

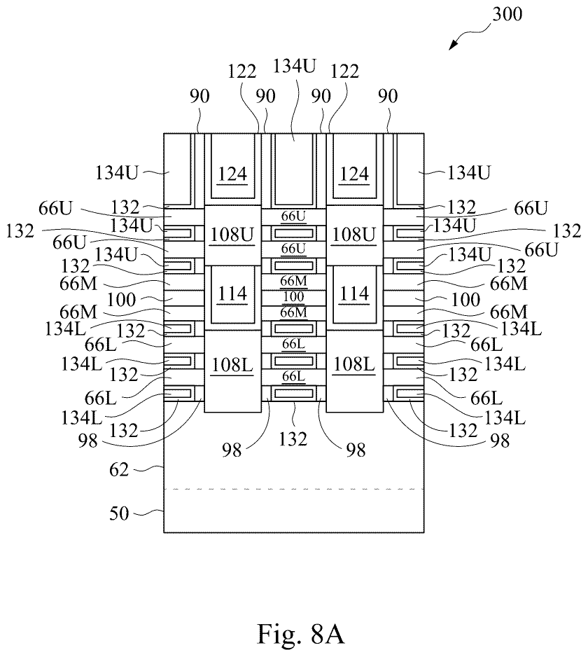

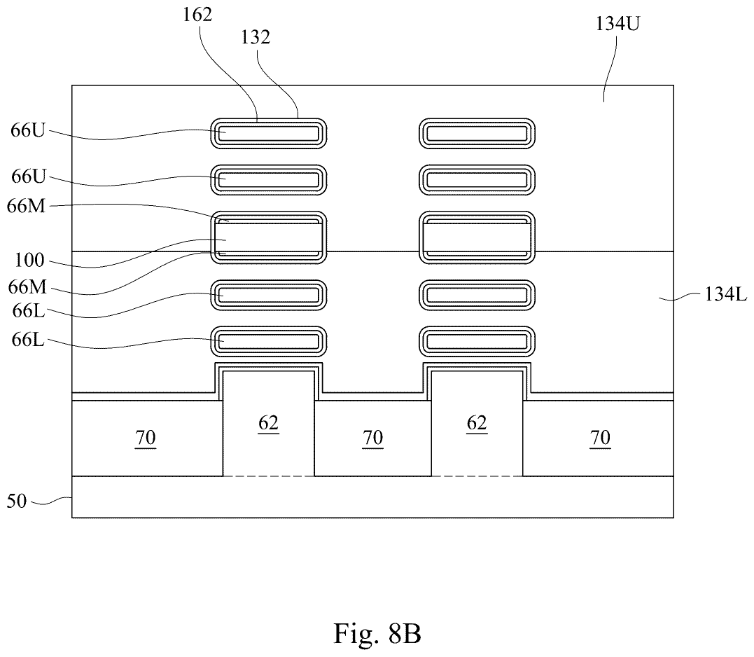

FIGS. 2-12 are three-dimensional views and cross-sectional views of a CFET device 300 at various stages of manufacturing, in accordance with some embodiments of the present disclosure. FIGS. 2, 3, and 4 are three-dimensional views showing a similar three-dimensional view as FIG. 1. FIGS. 5, 6, 7, and 8A illustrate cross-sectional views along a similar cross-section as reference cross-section A-A′ in FIG. 1. FIGS. 8B and 9-12 illustrate cross-sectional views along a similar cross-section as reference cross-section B-B′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

A multi-layer stack 52 is formed over the substrate 50. The multi-layer stack 52 includes alternating dummy layers 54 (including first dummy layers 54A and a second dummy layer 54B) and semiconductor layers 56 (including lower semiconductor layers 56L and upper semiconductor layers 56U). The lower semiconductor layers 56L and a subset of the first dummy layers 54A are disposed below the second dummy layer 54B. The upper semiconductor layers 56U and another subset of the first dummy layers 54A are disposed above the second dummy layer 54B. As subsequently described in greater detail, the dummy layers 54 will be removed and the semiconductor layers 56 will be patterned to form channel regions of CFETs. Specifically, the lower semiconductor layers 56L will be patterned to form channel regions of the lower nanostructure-FETs of the CFETs, and the upper semiconductor layers 56U will be patterned to form channel regions of the upper nanostructure-FETs of the CFETs.

The multi-layer stack 52 is illustrated as including six of the dummy layers 54 and six of the semiconductor layers 56. It is appreciated that the multi-layer stack 52 may include any number of the dummy layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A are formed of a first semiconductor material, and the second dummy layer 54B is formed of a second semiconductor material. The first and second semiconductor materials may be selected from the candidate semiconductor materials of the substrate 50. The semiconductor materials of the first dummy layers 54A and the second dummy layer 54B will be subsequently described in greater detail. The first and second semiconductor materials have a high etching selectivity to one another. As such, the material of the second dummy layer 54B may be removed at a faster rate than the material of the first dummy layers 54A in subsequent processing.

The semiconductor layers 56 (including the lower semiconductor layers 56L and upper semiconductor layers 56U) are formed of one or more semiconductor material(s). The semiconductor material(s) may be selected from the candidate semiconductor materials of the substrate 50. In some embodiments, the semiconductor layers 56 are formed of a group IV-V material or a group III-V material. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both be formed of a semiconductor material suitable for p-type devices and n-type devices, such as silicon. In some embodiments, the lower semiconductor layers 56L are formed of a semiconductor material suitable for p-type devices, such as germanium or silicon-germanium, and the upper semiconductor layers 56U are formed of a semiconductor material suitable for n-type devices, such as silicon or carbon-doped silicon. The semiconductor material(s) of the semiconductor layers 56 will be subsequently described in greater detail. The semiconductor material(s) of the semiconductor layers 56 have a high etching selectivity to the semiconductor materials of the dummy layers 54. As such, the materials of the dummy layers 54 may be removed at a faster rate than the material of the semiconductor layers 56 in subsequent processing.

Some layers of the multi-layer stack 52 may be thicker than other layers of the multi-layer stack 52. The thickness of the second dummy layer 54B may be different (e.g., greater or less) than the thickness of each of the first dummy layers 54A. In some embodiments, the second dummy layer 54B has a large thickness, such as a greater thickness than each of the first dummy layers 54A. Forming the second dummy layer 54B to a large thickness allows the second dummy layer 54B to be more easily removed in subsequently processing. Additionally, the thickness of each of the semiconductor layers 56 may be different (e.g., greater or less) than the thickness(es) of each of the first dummy layers 54A and/or the second dummy layer 54B. In some embodiments, each of the semiconductor layers 56 may be thicker than each of the dummy layers 54.

In some embodiments, the first dummy layers 54A are formed of silicon-germanium with a first germanium atomic percentage, the second dummy layer 54B is formed of silicon-germanium with a second germanium atomic percentage that is higher than the first germanium atomic percentage. The difference between the second germanium atomic percentage and the first germanium atomic percentage may be higher than about 25 percent, and may be in the range between about 35 percent and about 75 percent. The higher germanium atomic percentage allows the second dummy layer 54B to be etched at a faster rate than the first dummy layers 54A, and allow the second dummy layer 54B to be completed removed during a subsequent etching process, as discussed hereinafter.

In FIG. 3, fins 62 are formed in the substrate 50 and nanostructures 64, 66 (including first dummy nanostructures 64A, second dummy nanostructures 64B, lower semiconductor nanostructures 66L, middle semiconductor nanostructures 66M, and upper semiconductor nanostructures 66U) are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower semiconductor nanostructures 66L from some of the lower semiconductor layers 56L, the upper semiconductor nanostructures 66U from some of the upper semiconductor layers 56U, and the middle semiconductor nanostructures 66M from some of the lower semiconductor layers 56L and some of the upper semiconductor layers 56U. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66.

As subsequently described in greater detail, the dummy nanostructures 64 will be removed to form vertically arranged channel regions of CFETs. Specifically, the lower semiconductor nanostructures 66L will act as channel regions for lower nanostructure-FETs of the CFETs. Additionally, the upper semiconductor nanostructures 66U will act as channel regions for upper nanostructure-FETs of the CFETs.

The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs. The second dummy nanostructures 64B will be subsequently replaced with isolation structures. The isolation structures and the middle semiconductor nanostructures 66M may define boundaries of the lower nanostructure-FETs and the upper nanostructure-FETs.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66. In some embodiments, a mask (or other layer) may remain on the nanostructures 64, 66.

Although each of the fins 62 and the nanostructures 64, 66 are illustrated as having a constant width throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in cross-section view.

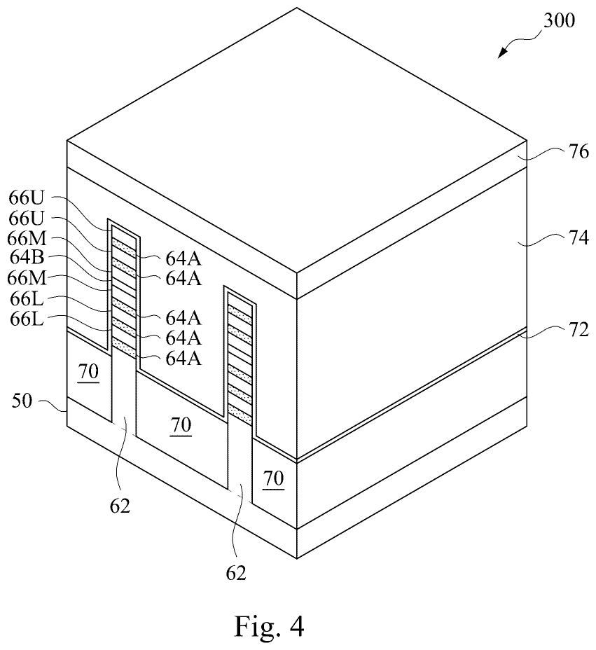

In FIG. 4, isolation regions 70 are formed adjacent to the fins 62. The isolation regions 70 may be formed by depositing an insulating material over the substrate 50, the fins 62, and nanostructures 64, 66, and between adjacent fins 62. The insulating material may be an oxide, such as silicon oxide, a nitride, the like, or a combination thereof, and may be formed by high-density plasma chemical vapor deposition (HDP-CVD), flowable chemical vapor deposition (FCVD), the like, or a combination thereof. Other insulating materials formed by any acceptable process may be used. In some embodiments, the insulating material is silicon oxide formed by an FCVD process. An anneal process may be performed once the insulating material is formed. In an embodiment, the insulating material is formed such that excess insulating material covers the nanostructures 64, 66. Although the insulating material is illustrated as a single layer, some embodiments may utilize multiple layers. For example, in some embodiments a liner (not separately illustrated) may first be formed along a surface of the substrate 50, the fins 62, and the nanostructures 64, 66. Thereafter, a fill material, such as one of the previously described insulating materials may be formed over the liner.

A removal process is then applied to the insulating material to remove excess insulating material over the nanostructures 64, 66. In some embodiments, a planarization process such as a chemical mechanical polish (CMP), an etch-back process, combinations thereof, or the like may be utilized. The planarization process exposes the nanostructures 64, 66 such that top surfaces of the nanostructures 64, 66 and the insulating material are level after the planarization process is complete.

The insulating material is then recessed to form the isolation regions 70. The insulating material is recessed such that upper portions of the fins 62 protrude from between neighboring isolation regions 70. Further, the top surfaces of the isolation regions 70 may have a flat surface as illustrated, a convex surface, a concave surface (such as dishing), or a combination thereof. The top surfaces of the isolation regions 70 may be formed flat, convex, and/or concave by an appropriate etch. The isolation regions 70 may be recessed using an etching process, such as one that is selective to the insulating material (e.g., selectively etches the insulating material at a faster rate than the materials of the fins 62 and the nanostructures 64, 66). For example, an oxide removal using, for example, dilute hydrofluoric (dHF) acid may be used.

In FIG. 4, a dummy dielectric layer 72 is formed on the fins 62 and/or the nanostructures 64, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), or the like. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 64, 66.

Next, in FIG. 5, the mask layer 76 is patterned using acceptable photolithography and etching techniques to form masks 86. The pattern of the masks 86 is then transferred to the dummy gate layer 74 and to the dummy dielectric layer 72 to form dummy gates 84 and dummy dielectrics 82, respectively. The dummy gates 84 and the dummy dielectrics 82 are collectively referred to as dummy gate stacks 85. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

In FIG. 5, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the dummy gates 84 (thus forming the gate spacers 90). Fin spacers may also be formed as part of forming the gate spacers 90.

Source/drain recesses 94 are formed in the nanostructures 64, 66, and the fins 62. Epitaxial source/drain regions will be subsequently formed in the source/drain recesses 94. The source/drain recesses 94 may extend through the nanostructures 64, 66 and into the fins 62. The fins 62 may be etched such that bottom surfaces of the source/drain recesses 94 are disposed above, below, or level with the top surfaces of the isolation regions 70. The source/drain recesses 94 may be formed by etching the nanostructures 64, 66, and the substrate 50 using anisotropic etching processes, such as RIE, NBE, or the like. The gate spacers 90 and the dummy gates 84 mask portions of the nanostructures 64, 66, and the fins 62 during the etching processes used to form the source/drain recesses 94. A single etch process or multiple etch processes may be used to etch each layer of the nanostructures 64, 66, and the fins 62. Timed etch processes may be used to stop the etching of the source/drain recesses 94 after the source/drain recesses 94 reach a desired depth.

Next, in FIG. 6, inner spacers 98 and dielectric isolation layers 100 are formed. Forming inner spacers 98 and dielectric isolation layers 100 (also referred to as isolation structures 100) may include an etching process that laterally etches the dummy nanostructures 64A and removes the dummy nanostructure 64B. The etching process may be isotropic and may be selective to the material of the dummy nanostructures 64, so that the dummy nanostructures 64 are etched at a faster rate than the semiconductor nanostructures 66. The etching process may also be selective to the material of the dummy nanostructures 64B, so that the dummy nanostructures 64B are etched at a faster rate than the dummy nanostructures 64A. In this manner, the dummy nanostructures 64B may be completely removed from between the middle semiconductor nanostructures 66M without completely removing the dummy nanostructures 64A. In some embodiments where the dummy nanostructures 64B are formed of germanium or silicon germanium with a higher germanium atomic percentage than the dummy nanostructures 64A, the dummy nanostructures 64A are formed of silicon germanium with a lower germanium atomic percentage than the dummy structures 64B, and the semiconductor nanostructures 66 are formed of silicon free from germanium, the etch process may comprise a dry etch process using chlorine-containing gas, with or without a plasma. Because the dummy gate stacks 85 wrap around sidewalls of the semiconductor nanostructures 66 (see FIG. 4), the dummy gate stacks 85 may support the upper semiconductor nanostructures 66U so that the upper semiconductor nanostructures 66U do not collapse upon removal of the dummy nanostructures 64B. Further, although sidewalls of the dummy nanostructures 64A are illustrated as being straight after the etching, the sidewalls may be concave or convex.

Inner spacers 98 are formed on sidewalls of the recessed dummy nanostructures 64A, and dielectric isolation layers 100 are formed between the middle semiconductor nanostructures 66M. As subsequently described in greater detail, source/drain regions will be subsequently formed in the source/drain recesses 94, and the dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as the etch processes used to form gate structures. Dielectric isolation layers 100, on the other hand, are used to isolate the upper semiconductor nanostructures 66U (collectively) from the lower semiconductor nanostructures 66L (collectively). Further, the middle semiconductor nanostructures 66M and the dielectric isolation layers 100 may define the boundaries of the lower nanostructure-FETs and the upper nanostructure-FETs.

The inner spacers 98 and the dielectric isolation layers 100 may be formed by conformally depositing an insulating material in the source/drain recesses 94, on sidewalls of the dummy nanostructures 64A, and between the middle semiconductor nanostructures 66M, and then etching the insulating material. The insulating material may be a non-low-k dielectric material, which may be a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining in the sidewalls of the dummy nanostructures 64A (thus forming the inner spacers 98) and has portions remaining in between the middle semiconductor nanostructures 66M (thus forming the dielectric isolation layers 100).

As also illustrated by FIG. 6, lower epitaxial source/drain regions 108L and upper epitaxial source/drain regions 108U are formed. The lower epitaxial source/drain regions 108L are formed in the lower portions of the source/drain recesses 94. The lower epitaxial source/drain regions 108L are in contact with the lower semiconductor nanostructures 66L and are not in contact with the upper semiconductor nanostructures 66U. Inner spacers 98 electrically insulate the lower epitaxial source/drain regions 108L from the dummy nanostructures 64A, which will be replaced with replacement gates in subsequent processes.

The lower epitaxial source/drain regions 108L are epitaxially grown, and have a conductivity type that is suitable for the device type (p-type or n-type) of the lower nanostructure-FETs. When lower epitaxial source/drain regions 108L are n-type source/drain regions, the respective material may include silicon or carbon-doped silicon, which is doped with an n-type dopant such as phosphorous, arsenic, or the like. When lower epitaxial source/drain regions 108L are p-type source/drain regions, the respective material may include silicon or silicon germanium, which is doped with a p-type dopant such as boron, indium, or the like. The lower epitaxial source/drain regions 108L may be in-situ doped, and may be, or may not be, implanted with the corresponding p-type or n-type dopants. During the epitaxy of the lower epitaxial source/drain regions 108L, the upper semiconductor nanostructures 66U may be masked to prevent undesired epitaxial growth on the upper semiconductor nanostructures 66U. After the lower epitaxial source/drain regions 108L are grown, the masks on the upper semiconductor nanostructures 66U may then be removed.

As a result of the epitaxy processes used for forming the lower epitaxial source/drain regions 108L, upper surfaces of the lower epitaxial source/drain regions 108L have facets which expand laterally outward beyond sidewalls of the nanostructures 64 and 66. In some embodiments, adjacent lower epitaxial source/drain regions 108L remain separated after the epitaxy process is completed. In other embodiments, these facets cause neighboring lower epitaxial source/drain regions 108L of a same FET to merge.

A first contact etch stop layer (CESL) 112 and a first interlayer dielectric (ILD) 114 are formed over the lower epitaxial source/drain regions 108L. The first CESL 112 may be formed of a dielectric material having a high etching selectivity from the etching of the first ILD 114, such as silicon nitride, silicon oxide, silicon oxynitride, or the like, which may be formed by any suitable deposition process, such as CVD, ALD, or the like. The first ILD 114 may be formed of a dielectric material, which may be deposited by any suitable method, such as CVD, plasma-enhanced CVD (PECVD), or FCVD. The applicable dielectric material of the first ILD 114 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 114, followed by a planarization process and then an etch-back process. In some embodiments, the first ILD 114 is etched first, leaving the first CESL 112 unetched. An anisotropic etching process is then performed to remove the portions of the first CESL 112 higher than the recessed first ILD 114. After the recessing, the sidewalls of the upper semiconductor nanostructures 66U are exposed.

Upper epitaxial source/drain regions 108U are then formed in the upper portions of the source/drain recesses 94. The upper epitaxial source/drain regions 108U may be epitaxially grown from exposed surfaces of the upper semiconductor nanostructures 66U. The materials of upper epitaxial source/drain regions 108U may be selected from the same candidate group of materials for forming lower source/drain regions 108L, depending on the desired conductivity type of upper epitaxial source/drain regions 108U. The conductivity type of the upper epitaxial source/drain regions 108U may be opposite the conductivity type of the lower epitaxial source/drain regions 108L. For example, the upper epitaxial source/drain regions 108U may be oppositely doped from the lower epitaxial source/drain regions 108L. The upper epitaxial source/drain regions 108U may be in-situ doped, and/or may be implanted, with an n-type or p-type dopant. Adjacent upper source/drain regions 108U may remain separated after the epitaxy process or may be merged.

After the epitaxial source/drain regions 108U are formed, a second CESL 122 and a second ILD 124 are formed. The materials and the formation methods may be similar to the materials and the formation methods of first CESL 112 and first ILD 114, respectively, and are not discussed in detail herein. The formation process may include depositing the layers for the second CESL 122 and the second ILD 124, and performing a planarization process to remove the excess portion of the corresponding layers. After the planarization process, top surfaces of the second ILD 124, the second CESL 122, the gate spacers 90, and the masks 86 are coplanar (within process variations). The planarization process may leave masks 86 unremoved (as shown), or may remove the masks 86, in which case the top surface of the second ILD 124 is level with the top surface of the dummy gate stacks 85.

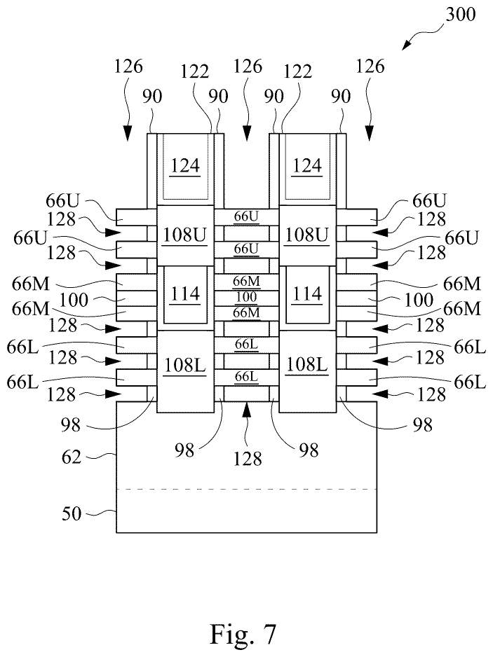

Next, in FIG. 7, the mask 86 (if not removed already) is removed, e.g., by a CMP process. Next, the dummy gate stacks 85 are removed in one or more etching steps, so that recesses 126 are formed between the gate spacers 90. In some embodiments, the dummy gates 84 and the dummy dielectrics 82 are removed by an anisotropic dry etch process. For example, the etching process may include a dry etch process using reaction gas(es) that selectively etch the material of the dummy gates 84. Each of the recesses 126 exposes and/or overlies portions of nanostructures 64, 66 which act as the channel regions in the resulting devices. The portions of the nanostructures 64, 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to form openings 128 in regions between the semiconductor nanostructures 66. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation structures 100. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation structures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings 128.

In FIGS. 8A-8B, gate dielectrics 132 are formed (e.g., conformally) over the nanostructures 66. In some embodiments, as illustrated in FIG. 8B, interfacial layers 162 are formed at exposed surfaces of the nanostructures 66 and the fins 62. In some embodiments, the interfacial layer 162 is formed of an oxide of a group II-VI material or an oxide of a group IV material. In the illustrated embodiment, the interfacial layer 162 is an oxide of the material of the nanostructures 66, and is formed by an oxidization process (e.g., a thermal oxidization process). In other words, the interfacial layer 162 is formed by converting (e.g., oxidizing) exterior portions of the nanostructures 66 into an oxide of the material of the nanostructures 66. As a result, the interfacial layer 162 is not formed on, e.g., the isolation structures 100 and the isolation regions 70, in the illustrated embodiment. In other embodiments, the interfacial layer 162 is formed by a deposition process (e.g., CVD), in which case the interfacial layer 162 is also formed on, e.g., the isolation structures 100 and the isolation regions 70. In some embodiments, the interfacial layer 162 is omitted, as illustrated in the simplified drawing as shown in FIG. 8A. These and other variations are fully intended to be included within the scope of the present disclosure.

Next, a gate dielectric layer 132 is formed (e.g., conformally) over the interfacial layer 162 and along sidewalls of the isolation structures 100, such that the gate dielectric layer 132 conformally lines the recesses 126 and the openings 128. Specifically, the gate dielectric layer 132 is formed on the top surfaces of the fins 62; on the top surfaces, the sidewalls, and the bottom surfaces of the semiconductor nanostructures 66; along sidewalls of the isolation structures 100; and along the sidewalls of the gate spacers 90. The gate dielectric layer 132 wraps around all (e.g., four) sides of the semiconductor nanostructures 66. The gate dielectric layer 132 may also be formed on the sidewalls of the fins 62 (e.g., in embodiments where the top surfaces of the isolation regions 70 are below the top surfaces of the fins 62).

The gate dielectric layer 132 may include an oxide such as silicon oxide or a metal oxide, a silicate such as a metal silicate, combinations thereof, multi-layers thereof, or the like. The gate dielectric layer 132 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectric layer 132 may include molecular-beam deposition (MBD), ALD, PECVD, and the like.

Next, a lower gate electrode 134L is formed in openings 128 below the isolation structures 100 to surround the lower semiconductor nanostructures 66L, and an upper gate electrode 134U is formed in openings 128 above the isolation structures 100. In some embodiments, the lower gate electrode 134L and the upper gate electrode 134U each include one or more metal layers. For example, each of the lower gate electrode 134L and the upper gate electrode 134U may include one or more work function metal layers stacked one over another and a fill metal filling up a remainder of the openings 128. The one or more work function metal layers in the lower gate electrode 134L provide a suitable work function for the lower nanostructure-FET, and. the one or more work function metal layers in the upper gate electrode 134U provide a suitable work function for the upper nanostructure-FET. For a p-type FET, the gate electrode 134L or 134U may include one or more p-type work function metal (P-metal) layers. The p-type work function metal may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials. For an n-type FET, the gate electrode 134L or 134U may include one or more n-type work function metal (N-metal) layers. The n-type work function metal may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. In some embodiments, the fill metal in the lower gate electrode 134L and the upper gate electrode 134U may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials.

In some embodiments, formation of the lower gate electrode 134L and upper gate electrode 134U comprises, for example, depositing one or more metal materials of the lower gate electrode 134L in the recesses 126 and the openings 128, etching back the one or more metal materials from the upper semiconductor nanostructures 66U, forming one or more metal materials of the upper gate electrode 134U over the upper semiconductor nanostructures 66U, followed by performing a CMP process on the metal materials of the upper gate electrode 134U and the gate dielectrics 132 until the second ILD 124 is exposed.

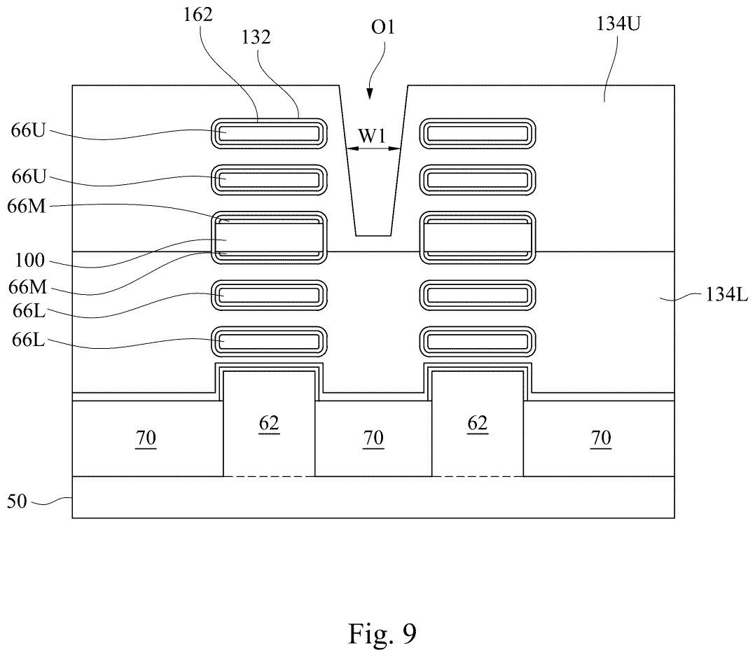

In FIG. 9, a front-side metal gate cutting process (also called front-side CMG process) is performed to form an upper CMG opening O1 in the upper gate electrode 134U. In some embodiments, this process involves etching a region of the upper gate electrode 134U laterally between the upper semiconductor nanostructures 66U, while a patterned mask protects other regions of the upper gate electrode 134U. In some embodiments, the etching process is a time-controlled etching process, wherein the etching duration is controlled such that the CMG opening O1 has a bottom lower than top surfaces of the isolation structures 100. In some embodiments as illustrated in FIG. 9, the bottom of the CMG opening O1 is higher than bottom surfaces of the isolation structures 100. In some other embodiments, the bottom of the CMG opening O1 is level with or lower than the bottom surfaces of the isolation structures 100.

In some embodiments, the CMG opening O1 has a tapered cross-sectional profile due to the etching process (e.g., anisotropic etching process). In particular, the CMG opening O1 has a width W1 continuously decreasing in a direction towards the substrate 50. Consequently, the CMG opening O1 has its maximum width at the top and its minimum width at the bottom. This tapering effect is due to the etching process, which causes the bottom width of the CMG opening O1 to decrease with increasing depth. By controlling the etching duration, the upper CMG opening O1 does not extends through a cumulative height of the upper gate electrode 134U and the lower gate electrode 134L. The upper CMG opening O1 thus has a depth less than the cumulative height of the upper gate electrode 134U and the lower gate electrode 134L. This controlled etching prevents the bottom width of the upper CMG opening O1 from becoming excessively narrow, which could otherwise lead to an undesirable increase in gate-to-gate capacitance between the upper gate electrodes 134U on opposite sides of the upper CMG opening O1.

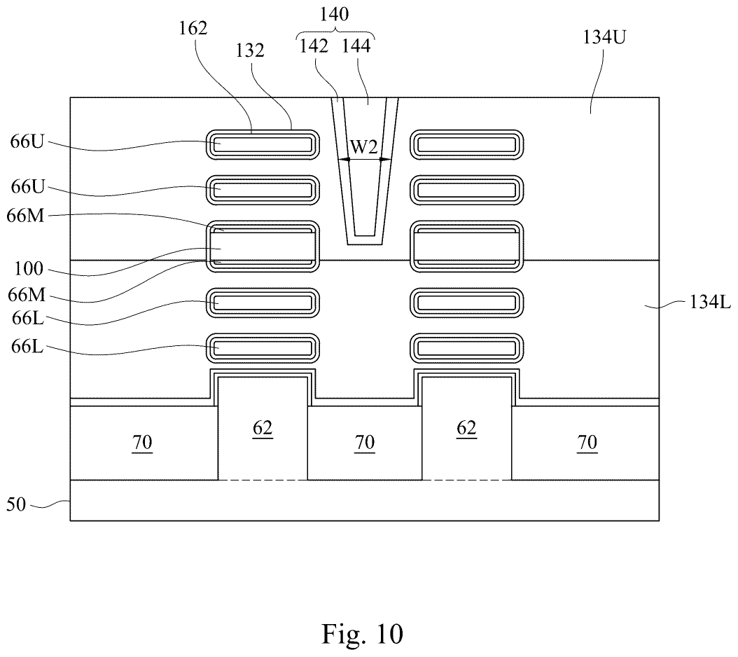

In FIG. 10, an upper gate isolation plug 140 is formed in the upper CMG opening O1. The upper gate isolation plug 140 can be referred to as an upper CMG isolation structure or a front-side CMG (FCMG) isolation structure. In some embodiments, the upper gate isolation plug 140 is a multi-layer structure including, for example, a first dielectric layer 142 and a second dielectric layer 144 over the first dielectric layer 142. In some embodiments, the second dielectric layer 144 is formed of a dielectric material different from the dielectric material of the first dielectric layer 142, and the dielectric constant of the second dielectric layer 144 may be less than that of the first dielectric layer 142. The reduced dielectric constant allows for further reducing the gate-to-gate capacitance between the upper gate electrodes 134U on opposite sides of the upper gate isolation plug 140. For example, the first dielectric layer 142 includes a nitride-based material (e.g., silicon nitride), and the second dielectric layer 144 includes an oxide-based material (e.g., silicon oxide). In some embodiments, the upper gate isolation plug 140 is formed by, for example, depositing a material of the first dielectric layer 142 into the upper CMG opening O1, depositing a material of the second dielectric layer 144 over the material of the first dielectric layer 142 and overfilling the upper CMG opening O1, followed by a CMP process performed to remove excessive materials of the first and second dielectric layers 142 and 144 outside the upper CMG opening O1 until the upper gate electrodes 134U are exposed.

In some embodiments, the upper gate isolation plug 140 is confined by the upper CMG opening O1, resulting in a tapered cross-sectional profile that mirrors the shape of the upper CMG opening O1. In particular, the upper gate isolation plug 140 has a width W2 continuously decreasing in a direction towards the substrate 50. Consequently, the upper gate isolation plug 140 has its maximum width at the top and its minimum width at the bottom. This tapering effect is attributed to the etching process used to create the upper CMG opening O1, which causes the bottom width of the upper gate isolation plug 140 to decrease as the height increases. By controlling the etching duration, the upper gate isolation plug 140 does not extends through a cumulative height of the upper gate electrode 134U and the lower gate electrode 134L. The upper gate isolation plug 140 thus has a height less than the cumulative height of the upper gate electrode 134U and the lower gate electrode 134L. This controlled height prevents the bottom width of the upper gate isolation plug 140 from becoming excessively narrow, thereby preventing an undesirable increase in gate-to-gate capacitance between the upper gate electrodes 134U on either side of the isolation plug 140.

Additional processing may be performed after the processing of FIG. 10 to complete fabrication of the CFET device 300, as skilled artisans readily appreciate. For example, source/drain contact plugs, gate contact plugs, and front-side interconnect structures may be formed to interconnect the electrical components formed and to form functional circuits. Details are not discussed here.

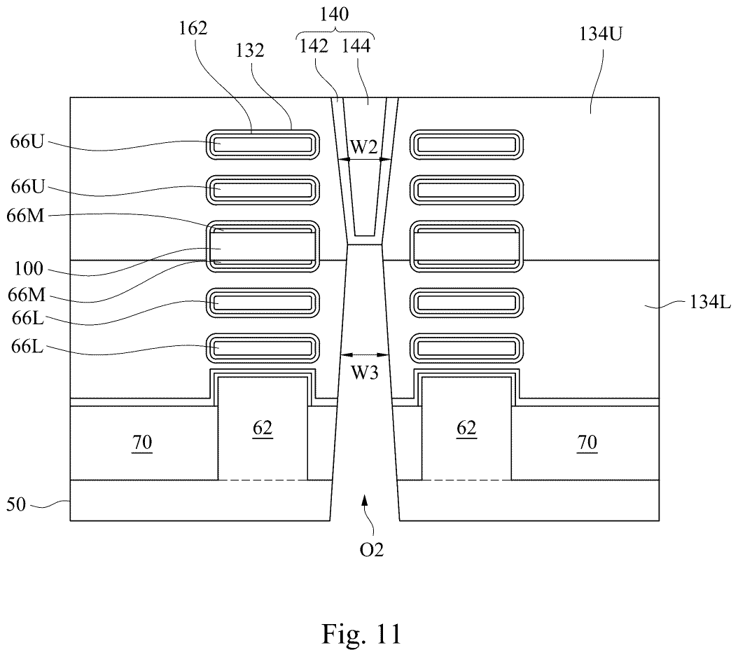

In FIG. 11, a backside metal gate cutting process (also called backside CMG process) is performed to form a lower CMG opening O2 in the lower gate electrode 134L. In some embodiments, this process involves initially etching a region at a backside surface of the substrate 50 such that a region of the lower gate electrode 134L laterally between the lower semiconductor nanostructures 66L is finally etched, continuing until the bottom end of the upper gate isolation plug 140 is exposed within the lower CMG opening O2. During this etching step, other regions of the backside surface of the substrate 50 may be protected using a patterned mask formed from suitable lithography processes. In some embodiments, the etching process is a time-controlled etching process, wherein the etching duration is controlled such that the lower CMG opening O2 has a top not lower than the bottom end of the upper gate isolation plug 140. For example, the etching duration may be controlled such that the top of the lower CMG opening O2 is level with the bottom end of the upper gate isolation plug 140 as illustrated in FIG. 11, or the etching duration may be controlled such that the top of the lower CMG opening O2 is higher than the bottom end of the upper gate isolation plug 140. In some embodiments, the etching process is a selective etching process which etches the metal materials in the lower and upper gate electrodes 134L and 134U at a faster etch rate than etching the dielectric materials in the upper gate isolation plug 140. This selectivity allows the upper gate isolation plug 140 to act as a detectable endpoint for the etching process, enabling the etching process to be slowed down or halted when the lower CMG opening O2 reaches the upper gate isolation plug 140.

In some embodiments as illustrated in FIG. 11, the top of the lower CMG opening O2 is higher than the bottom surfaces of the isolation structures 100. In some embodiments, the top of the lower CMG opening O2 is lower than the top surfaces of the isolation structures 100. In some other embodiments, the top of the lower CMG opening O2 is level with or higher than the top surfaces of the isolation structures 100.

In some embodiments, the lower CMG opening O2 has a tapered cross-sectional profile due to the etching process (e.g., anisotropic etching process). In particular, the lower CMG opening O2 has a width W3 continuously decreasing in a direction towards the upper gate isolation structure 140. Consequently, the lower CMG opening O2 has its maximum width at the bottom and its minimum width at the top. This tapering effect is due to the etching process, which causes the top width of the lower CMG opening O2 to decrease with increasing depth. By controlling the etching duration, the lower CMG opening O2 does not extends through a cumulative height of the upper gate electrode 134U and the lower gate electrode 134L. The lower CMG opening O2 thus has a depth less than the cumulative height of the upper gate electrode 134U and the lower gate electrode 134L. This controlled etching prevents the top width of the lower CMG opening O2 from becoming excessively narrow, which could otherwise lead to an undesirable increase in gate-to-gate capacitance between the upper gate electrodes 134U on opposite sides of the lower CMG opening O2 and between lower gate electrodes 134L on opposite sides of the lower CMG opening O2.

The etching process for forming the lower CMG opening O2 initiates from the backside surface of the substrate 50, while the etching process for forming the upper CMG opening O1 initiates from the front-side of the upper gate electrode 134U. Consequently, the lower CMG opening O2 and the upper CMG opening O1 taper in opposite directions. This also means that the lower CMG opening O2 and the upper gate isolation plug 140 taper in opposite directions. Specifically, the width W2 of the upper gate isolation plug 140 continuously decreases in a direction towards the lower CMG opening O2, and the width W3 of the lower CMG opening O2 continuously decreases in a direction towards the upper gate isolation plug 140.

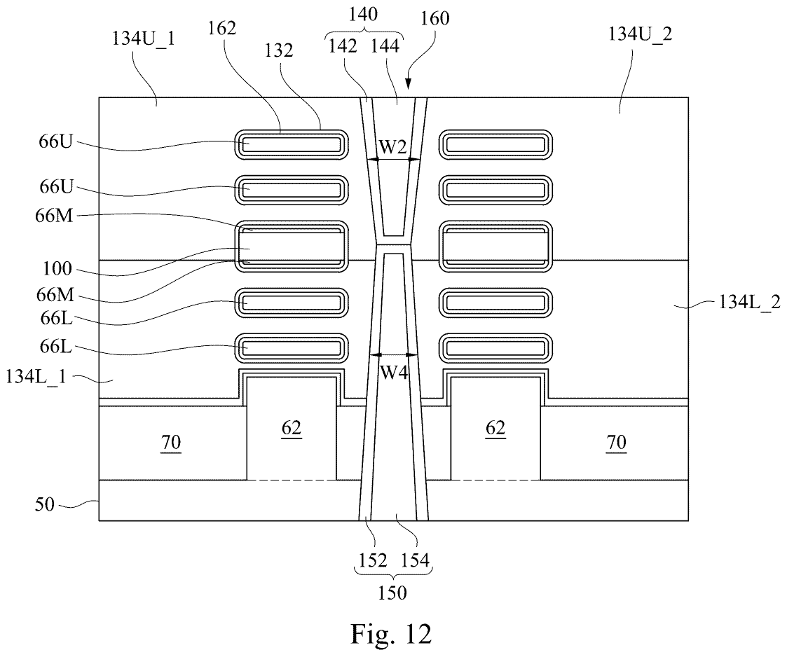

In FIG. 12, a lower gate isolation plug 150 is formed in the lower CMG opening O2. The lower gate isolation plug 150 can be referred to as a lower CMG isolation structure or a backside CMG (BCMG) isolation structure. In some embodiments, the lower gate isolation plug 150 is a multi-layer structure including, for example, a first dielectric layer 152 and a second dielectric layer 154 wrapped around by the first dielectric layer 152. In some embodiments, the second dielectric layer 154 is formed of a dielectric material different from the dielectric material of the first dielectric layer 152, and the dielectric constant of the second dielectric layer 154 may be less than that of the first dielectric layer 152. The reduced dielectric constant allows for further reducing the gate-to-gate capacitance between the lower gate electrodes 134L on opposite sides of the lower gate isolation plug 150 and the upper gate electrodes 134U on opposite sides of the lower gate isolation plug 150. For example, the first dielectric layer 152 includes a nitride-based material (e.g., silicon nitride), and the second dielectric layer 154 includes an oxide-based material (e.g., silicon oxide). In some embodiments, the lower gate isolation plug 150 is formed by, for example, depositing a material of the first dielectric layer 152 into the lower CMG opening O2, depositing a material of the second dielectric layer 154 over the material of the first dielectric layer 152 and overfilling the lower CMG opening O2, followed by a CMP process performed to remove excessive materials of the first and second dielectric layers 152 and 154 outside the lower CMG opening O2 until the backside surface of the substrate 50 is exposed.

The upper gate isolation plug 140 and the lower gate isolation plug 150 collectively serve as a gate isolation plug 160 that vertically extends through the upper gate electrode 134U and the lower gate electrode 134L to break the continuous upper gate electrode 134U into separate upper gate electrodes 134U_1 and 134U_2, and break the continuous lower gate electrode 134L into separate lower gate electrodes 134L_1 and 134L_2. As a result, the gate isolation plug 160 electrically isolates the upper gate electrodes 134U_1 and 134U_2, allowing them to be controlled independently. Likewise, the gate isolation plug 160 electrically isolates the lower gate electrodes 134L_1 and 134L_2, enabling independent control of these lower gate electrodes 134L_1 and 134L_2 as well.

In some embodiments, the lower gate isolation plug 150 is confined by the lower CMG opening O2, resulting in a tapered cross-sectional profile that mirrors the shape of the lower CMG opening O2. In particular, the lower gate isolation plug 150 has a width W4 continuously decreasing in a direction towards the upper gate isolation plug 140. Consequently, the lower gate isolation plug 150 has its maximum width at the bottom and its minimum width at the top. This tapering effect is attributed to the etching process used to create the lower CMG opening O2, which causes the top width of the lower gate isolation plug 150 to decrease as the height increases. By controlling the etching duration, the lower gate isolation plug 150 does not extends through a cumulative height of the upper gate electrode 134U and the lower gate electrode 134L. The lower gate isolation plug 150 thus has a height less than the cumulative height of the upper gate electrode 134U and the lower gate electrode 134L. This controlled height prevents the top width of the lower gate isolation plug 150 from becoming excessively narrow, thereby preventing an undesirable increase in gate-to-gate capacitance between the lower gate electrodes 134L on opposite sides of the lower gate isolation plug 150 and between the upper gate electrodes 134U on opposite sides of the lower gate isolation plug 150.

As illustrated in FIG. 12, in some embodiments the lower gate isolation plug 150 and the upper gate isolation plug 140 taper in opposite directions. Specifically, the width W2 of the upper gate isolation plug 140 continuously decreases in a direction towards the lower gate isolation plug 150, and the width W4 of the lower gate isolation plug 150 continuously decreases in a direction towards the upper gate isolation plug 140. The lower gate isolation plug 150 has a height measured from a bottom end of the lower gate isolation plug 150 to a top end of the lower gate isolation plug 150, the upper gate isolation plug has a height measured from a bottom end of the upper gate isolation plug 140 to a top end of the upper gate isolation plug 140. In some embodiments, the height of the lower gate isolation plug 150 is greater than the height of the upper gate isolation plug 140, because the lower gate isolation plug 150 not only extends through a height of the lower gate electrode 134L, but also extends through a height of the isolation region 70 and a height of the substrate 50, while the upper gate isolation plug 140 extends through only a partial height of the upper gate electrode 134U.

In some embodiments, an interface formed by the upper gate isolation plug 140 and the lower gate isolation plug 150 is at an elevation higher than bottom surfaces of isolation structures 100 and lower than top surfaces of the isolation structures 100. In some embodiments, the interface formed by the upper gate isolation plug 140 and the lower gate isolation plug 150 is at an elevation higher than an interface formed by the upper gate electrode 134U_1 and the lower gate electrode 134L_1.

In some embodiments, the first dielectric layer 142 of the upper gate isolation plug 140 is formed of a same dielectric material as the first dielectric layer 152 of the lower gate isolation plug 150. In some embodiments, the first dielectric layer 142 of the upper gate isolation plug 140 is formed of a different dielectric material than the first dielectric layer 152 of the lower gate isolation plug 150. In some embodiments, the second dielectric layer 144 of the upper gate isolation plug 140 is formed of a same dielectric material as the second dielectric layer 154 of the lower gate isolation plug 150. In some embodiments, the second dielectric layer 144 of the upper gate isolation plug 140 is formed of a different dielectric material than the second dielectric layer 154 of the lower gate isolation plug 150.

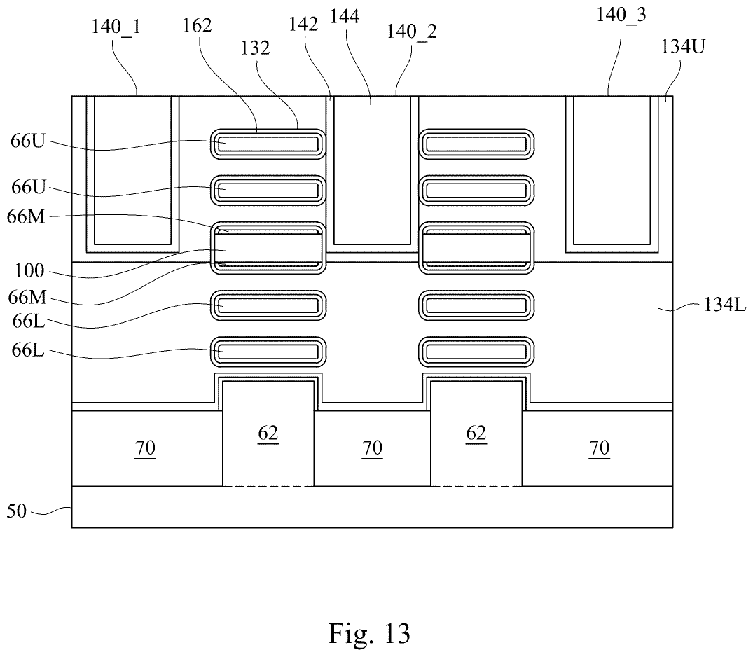

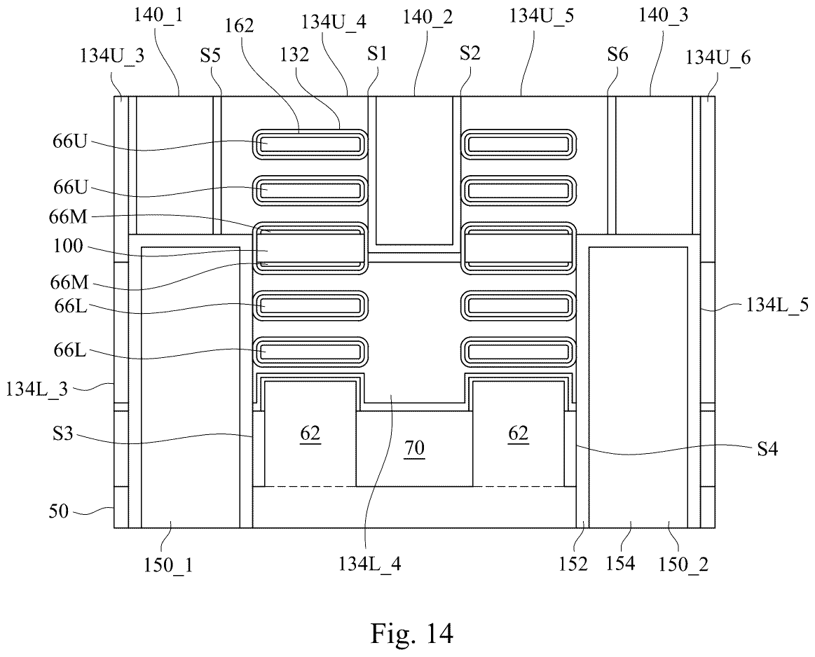

FIGS. 13-14 are cross-sectional views of a CFET device at various stages of manufacturing, in accordance with some other embodiments of the present disclosure. FIGS. 13-14 illustrate cross-sectional views along a similar cross-section as reference cross-section B-B′ in FIG. 1. The structure illustrated in FIG. 13 is similar to that illustrated in FIG. 10, except that three upper gate isolation plugs 140_1, 140_2, and 140_3 are formed in the upper gate electrode 134U. In some embodiments, each upper gate isolation plug includes a first dielectric layer 142 and second dielectric layer 144 as discussed previously with respect to the upper gate isolation plug 140. Formation steps of the upper gate isolation plugs 140_1, 140_2, and 140_3 are similar to that of the upper gate isolation plug 140, and thus are not repeated for the sake of brevity.

Next, in FIG. 14, two lower gate isolation plugs 150_1 and 150_2 are formed extending through various regions of the lower gate electrode 134L. The lower gate isolation plug 150_1 has a top end in contact with a bottom end of the upper gate isolation plug 140_1, and the lower isolation plug 150_2 has a top end in contact with a bottom end of the upper gate isolation plug 140_3. The bottom end of the upper gate isolation plug 140_2 is not in contact with any lower gate isolation plug. In particular, the bottom end of the upper gate isolation plug_2 is in contact with a metal material of either the upper gate electrode 134U or the lower gate electrode 134L. In some embodiments, each lower gate isolation plug includes a first dielectric layer 152 and second dielectric layer 154 as discussed previously with respect to the upper gate isolation plug 150. Formation steps of the lower gate isolation plugs 150_1 and 150_2 are similar to that of the lower gate isolation plug 150, and thus are not repeated for the sake of brevity.

These gate isolation plugs 140_1, 140_2, 140_3, 150_1 and 150_2 collectively separate the continuous upper gate electrode 134U into separate upper gate electrodes 134U_3, 134U_4, 134U5, 134U6, and further separate the lower gate electrode 134L into separate lower gate electrodes 134L_3, 134L_4 and 134L_5. The lower gate electrode 134L_4 vertically overlaps with both the upper gate electrodes 134U_4 and 134U_5, but is electrically isolated from the upper gate electrodes 134U_4 and 134U_5 by using the upper gate isolation plug 140_2, and the lower gate isolation plugs 150_1 and 150_2. In particular, the upper gate isolation plug 140_2 has a first sidewall S1 in contact with the gate dielectrics 132 around the upper semiconductor nanostructures 66U on the left side of the upper gate isolation plug 140_2, and a second sidewall S2 in contact with the gate dielectrics 132 around the upper semiconductor nanostructures 66U on the right of the upper gate isolation plug 140_2.

In some embodiments, the lower gate isolation plug 150_1 has a sidewall S3 in contact with gate dielectrics 132 around the lower semiconductor nanostructures 66L on the left side of the upper gate isolation plug 140_2. The lower gate isolation plug 150_2 has a sidewall S4 in contact with gate dielectrics 132 around the lower semiconductor nanostructures 66L on the right side of the upper gate isolation plug 140_2. This configuration allows for the lower gate electrode 134L_4 for forming a fork-sheet FET with the left lower semiconductor nanostructures 66L and another fork-sheet FET with the right lower semiconductor nanostructures 66L.

In some embodiments, the upper gate isolation structure 140_1 has a sidewall S5 closest to the upper semiconductor nanostructures 66U but laterally set back from or offset from the sidewall S3 of the lower gate isolation plug 150_1. This allows the upper gate electrode 134U_4 to wrap around three sides (including top side, bottom side, and left side) each of the upper semiconductor nanostructures 66U. However, the upper gate electrode 134U_4 does not wrap around the right sides of the upper semiconductor nanostructures 66U due to the presence of the upper gate isolation plug 140_2. This configuration allows the upper gate electrode 134U_4 for forming a fork-sheet FET with the upper semiconductor nanostructures 66U on the left side of the upper gate isolation plug 140_2.

In some embodiments, the upper gate isolation structure 140_3 has a sidewall S6 closest to the upper semiconductor nanostructures 66U but laterally set back from or offset from the sidewall S4 of the lower gate isolation plug 150_2. This allows the upper gate electrode 134U_5 to wrap around three sides (including top side, bottom side, and right side) of each of the upper semiconductor nanostructures 66U. However, the upper gate electrode 134U_5 does not wrap around the left sides of the upper semiconductor nanostructures 66U due to the presence of the upper gate isolation plug 140_2. This configuration allows the upper gate electrode 134U_5 for forming a fork-sheet FET with the upper semiconductor nanostructures 66U on the right side of the upper gate isolation plug 140_2. In some embodiments, these fork-sheet FETs illustrated in FIG. 14 can be utilized to create a flip-flop cell, which provides distinct voltages for NFET and PFET gates. This is achieved by electrically isolating the NFET gates (e.g., upper gate electrodes) from the PFET gates (e.g., lower gate electrodes) using the gate isolation plugs 140_1, 140_2, 140_3, 150_1 and 150_2.

In some embodiments, as illustrated in FIG. 14, the top ends of the lower gate isolation plugs 150_1 and 150_2 are higher than the top end of the upper gate isolation plug 140_2. This configuration results from the etching process used to form the lower CMG openings. The etching is controlled so that the top ends of the lower CMG openings are higher than the bottom ends of the upper gate isolation plugs 140_1, 140_2, and 140_3. This ensures that the continuous upper gate electrode 134U and the continuous lower gate electrode 134L are effectively segmented by the gate isolation plugs. Because the top end of the lower CMG opening for the gate isolation plug 150_1 is higher than the bottom end of the upper gate isolation plug 140_1, the lower portion of the upper gate isolation plug 140_1 may be removed during the etching process for forming the lower CMG opening. This removal may remove or trim the bottom horizontal portion of the first dielectric layer 142 within the upper gate isolation plug 140_1. Similarly, since the top end of the lower CMG opening for the gate isolation plug 150_2 is higher than the bottom end of the upper gate isolation plug 140_3, the lower portion of the upper gate isolation plug 140_3 may be removed during the etching process for forming the lower CMG opening. Therefore, this may also remove or trim the bottom horizontal portion of the first dielectric layer 142 within the upper gate isolation plug 140_3.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the undesirable increase in gate-to-gate capacitance can be prevented by using a dual-side CMG formation process. Another advantage is that the electrical isolation between upper gates and lower gates in CFET structures can be achieved by using the dual-side CMG formation process.

In some embodiments, a method includes forming a plurality of semiconductor nanostructures (e.g., 66L and 66U) arranged one above another over a substrate; forming a lower gate electrode (e.g., 134L) surrounding a first subset of the plurality of semiconductor nanostructures, forming an upper gate electrode (e.g., 134U) surrounding a second subset of the plurality of semiconductor nanostructures; forming an upper gate isolation structure (e.g., 140) extending from a top surface of the upper gate electrode into the upper gate electrode; and after completing the formation of the upper gate isolation structure, forming a lower gate isolation structure (e.g., 150) extending from a bottom end of the upper gate isolation structure into the lower gate electrode. In some embodiments, the bottom end of the upper gate isolation structure is higher than a top surface of a topmost one of the first subset of the plurality of semiconductor nanostructures. In some embodiments, forming the lower gate isolation structure comprises etching an opening extending from a backside surface of the substrate into the lower electrode, and depositing a metal into the opening. In some embodiments, the etching step of etching the opening is performed such that the bottom end of the upper gate isolation structure is exposed within the opening. In some embodiments, the upper gate isolation structure (e.g., 140) tapers in a first direction, and the lower gate isolation structure (e.g., 150) tapers in a second direction opposite to the first direction. In some embodiments, the lower gate isolation structure (e.g., 150) has a width increasing in a direction away from the upper gate isolation structure (e.g., 140). In some embodiments, the lower gate isolation structure (e.g., 150) has a minimal width a position higher than a top surface of a topmost one (e.g., topmost lower nanostructure 66L) of the first subset of the plurality of semiconductor nanostructures. In some embodiments, the method further includes forming a gate dielectric material around each of the plurality of semiconductor nanostructures. The lower gate isolation structure (e.g., 150_1 or 150_2) has a sidewall in contact with the gate dielectric material. In some embodiments, the upper gate isolation structure (e.g., 140_1 or 140_3) has a sidewall laterally offset from the sidewall of the lower gate isolation structure (e.g., 150_1 or 150_2). In some embodiments, the upper gate isolation structure is separated from the gate dielectric material by the upper gate electrode.

In some embodiments, a method includes forming a plurality of channel regions (e.g., 66L and 66U) stacked vertically over a fin; forming a dielectric isolation structure (e.g., 100) between a first subset of the plurality of channel regions (e.g., 66L) and a second subset of the plurality of channel regions (e.g., 66U); forming a gate dielectric material (e.g., 132) around the plurality of channel regions and the dielectric isolation structure; forming a lower gate electrode (e.g., 134L) around the first subset of the plurality of channel regions; forming an upper gate electrode (e.g., 134U) around the second subset of the plurality of channel regions; forming a first upper gate isolation structure (e.g., 140) in the upper gate electrode; and forming a lower gate isolation structure (e.g., 150) in the lower gate electrode, wherein the first upper gate isolation structure and the lower gate isolation structure are formed in separate deposition steps. In some embodiments, the deposition step of forming the lower gate isolation structure is performed after the deposition step of forming the first upper gate isolation structure. In some embodiments, the first upper gate isolation structure (e.g., 140_2) is in contact with the gate dielectric material around the second subset of the plurality of channel regions. In some embodiments, the first upper gate isolation structure (e.g., 140_2) has a bottom end covered by the upper gate electrode. In some embodiments, the method further includes forming a second upper gate isolation structure (e.g., 140_1) in the upper gate electrode, wherein the lower gate isolation structure (e.g., 150_1) is formed extending from a bottom end of the second upper gate isolation structure. In some embodiments, the lower gate isolation structure (e.g., 150_1) has a sidewall facing the first subset of the plurality of channel region, the second upper gate isolation structure (e.g., 140_1) has a sidewall facing the second subset of the plurality of channel regions, wherein the sidewall of the second upper gate isolation structure is laterally set back from the sidewall of the lower gate isolation structure.

In some embodiments, a device includes first channel regions (e.g., 66L) over a substrate; second channel regions (e.g., 66U) over the first channel regions; a first lower gate electrode (e.g., 134L_1) surrounding a first subset of the first channel regions in a cross-sectional view; a second lower gate electrode (e.g., 134L_2) surrounding a second subset of the first channel regions; a first upper gate electrode (e.g., 134U_1) over the first lower gate electrode and surrounding a first subset of the second channel regions; a second upper gate electrode (e.g., 134U_2) over the second lower gate electrode and surrounding a second subset of the second channel regions; a first upper gate isolation structure (e.g., 140) extending between the first upper gate electrode and the second upper gate electrode; and a lower gate isolation structure (e.g., 150) extending from a bottom end of the first upper gate isolation structure into the substrate. In some embodiments, the lower gate isolation structure (e.g., 150) narrows in a direction towards the first upper gate isolation structure (e.g., 140). In some embodiments, the first upper gate isolation structure (e.g., 140) narrows in a direction towards the lower gate isolation structure (e.g., 150). In some embodiments, the device further includes a second upper gate isolation structure (e.g., 140_2) having a top surface substantially level with the first upper gate isolation structure (e.g., 140_1 or 140_3), wherein a bottom surface of the second upper gate isolation structure is in contact with a material different from a material that a bottom surface of the first upper gate isolation structure is in contact with.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of semiconductor nanostructures arranged one above another over a substrate;
forming a lower gate electrode surrounding a first subset of the plurality of semiconductor nanostructures;
forming an upper gate electrode surrounding a second subset of the plurality of semiconductor nanostructures;
forming an upper gate isolation structure extending from a top surface of the upper gate electrode into the upper gate electrode; and
after completing the formation of the upper gate isolation structure, forming a lower gate isolation structure extending from a bottom end of the upper gate isolation structure into the lower gate electrode.

2. The method of claim 1, wherein the bottom end of the upper gate isolation structure is higher than a top surface of a topmost one of the first subset of the plurality of semiconductor nanostructures.

3. The method of claim 1, wherein forming the lower gate isolation structure comprises:
etching an opening extending from a backside surface of the substrate into the lower gate electrode; and
depositing a metal into the opening.

4. The method of claim 3, wherein the etching step of etching the opening is performed such that the bottom end of the upper gate isolation structure is exposed within the opening.

5. The method of claim 1, wherein the upper gate isolation structure tapers in a first direction, and the lower gate isolation structure tapers in a second direction opposite to the first direction.

6. The method of claim 1, wherein the lower gate isolation structure has a width increasing in a direction away from the upper gate isolation structure.

7. The method of claim 1, wherein the lower gate isolation structure has a minimal width a position higher than a top surface of a topmost one of the first subset of the plurality of semiconductor nanostructures.

8. The method of claim 1, further comprising:
forming a gate dielectric material around the plurality of semiconductor nanostructures, wherein the lower gate isolation structure has a sidewall in contact with the gate dielectric material.

9. The method of claim 8, wherein the upper gate isolation structure has a sidewall laterally offset from the sidewall of the lower gate isolation structure.

10. The method of claim 8, wherein the upper gate isolation structure is separated from the gate dielectric material by the upper gate electrode.

11. A method, comprising:
forming a plurality of channel regions stacked vertically over a fin;
forming a dielectric isolation structure between a first subset of the plurality of channel regions and a second subset of the plurality of channel regions;
forming a gate dielectric material around the plurality of channel regions and the dielectric isolation structure;
forming a lower gate electrode around the first subset of the plurality of channel regions;
forming an upper gate electrode around the second subset of the plurality of channel regions;
forming a first upper gate isolation structure in the upper gate electrode; and
forming a lower gate isolation structure in the lower gate electrode, wherein the first upper gate isolation structure and the lower gate isolation structure are formed in separate deposition steps.

12. The method of claim 11, wherein the deposition step of forming the lower gate isolation structure is performed after the deposition step of forming the first upper gate isolation structure.

13. The method of claim 11, wherein the first upper gate isolation structure is in contact with the gate dielectric material around the second subset of the plurality of channel regions.

14. The method of claim 11, wherein the first upper gate isolation structure has a bottom end covered by the upper gate electrode.

15. The method of claim 11, further comprising:
forming a second upper gate isolation structure in the upper gate electrode, wherein the lower gate isolation structure is formed extending from a bottom end of the second upper gate isolation structure.

16. The method of claim 15, wherein the lower gate isolation structure has a sidewall facing the first subset of the plurality of channel regions, the second upper gate isolation structure has a sidewall facing the second subset of the plurality of channel regions, wherein the sidewall of the second upper gate isolation structure is laterally set back from the sidewall of the lower gate isolation structure.

17. A device, comprising:
first channel regions over a substrate;
second channel regions over the first channel regions;
a first lower gate electrode surrounding a first subset of the first channel regions in a cross-sectional view;
a second lower gate electrode surrounding a second subset of the first channel regions in the cross-sectional view;
a first upper gate electrode over the first lower gate electrode and surrounding a first subset of the second channel regions in the cross-sectional view;
a second upper gate electrode over the second lower gate electrode and surrounding a second subset of the second channel regions in the cross-sectional view;
a first upper gate isolation structure extending between the first upper gate electrode and the second upper gate electrode; and
a lower gate isolation structure extending from a bottom end of the first upper gate isolation structure into the substrate.

18. The device of claim 17, wherein the lower gate isolation structure narrows in a direction towards the first upper gate isolation structure.

19. The device of claim 18, wherein the first upper gate isolation structure narrows in a direction towards the lower gate isolation structure.

20. The device of claim 17, further comprising:
a second upper gate isolation structure having a top surface substantially level with the first upper gate isolation structure, wherein a bottom surface of the second upper gate isolation structure is in contact with a material different from a material that a bottom surface of the first upper gate isolation structure is in contact with.
